(19) United States
(12) Patent Application Publication
(10) Pub. No.: US 2008/0316074 A1
(43) Pub. Date: Dec. 25, 2008

(54) Electronic Circuit and Semiconductor Device Having Dac and Scf

(75) Inventor: Taisuke Chida, Kyoto (JP)

Correspondence Address: ROHM CO., LTD.;C/O KEATING & BENNETT, LLP, 1800 Alexander Bell Drive, SUITE 200, Reston, VA, 20191, US

(73) Assignee: ROHM CO., LTD, Ukyo-ku, Kyoto (JP)

(21) Appl. No.: 11/574,752

(22) PCT Filed: Sep. 28, 2005
(86) PCT No.: PCT/JP05/18402

§ 371 Date: Mar. 6, 2007

(30) Foreign Application Priority Data
Oct. 5, 2004 (JP) 2004-292537

(51) Int. Cl. H03M 1/66; H03M 3/02

(52) U.S. Cl. 341/143; 341/150

(57) ABSTRACT

An electronic circuit has a voltage selection and output circuit, e.g. digital-to-analog converter (DAC), and a switched capacitor filter (SCF), in which operational conditions of the input side switches of the SCF are incorporated in the selection conditions for selecting respective multiple selection switches of the voltage selection and output circuit. This arrangement permits the selection switches to serve as the input side switches, thereby reducing in number serial switches such as MOS transistors in the circuit, and hence reducing the on-resistances of the serial switches, while preventing the clock feed-through thereof from increasing and suppressing output errors due to the linearity error of the buffer amplifier involved.

### BACKGROUND OF THE INVENTION

1. Field of the Invention

This invention relates to an electronic circuit and a semiconductor device, equipped with a digital-to-analog converter (DAC) and a switched capacitor filter circuit (SCF).

2. Description of the Related Art

Conventionally, a DAC for converting a digital signal into an analog signal and a SCF for filtering the analog signal outputted from the DAC are used in signal processing circuits of various electronic apparatuses (see, for example, Japanese Patent Applications Laid Open H11-308108 and H06-204866).

A typical DAC 10 and an SCF 20 have arrangements as shown in FIG. 6. The DAC 10 of FIG. 6 includes a resistive voltage division circuit having series resistors 11-0-11-N connected between a power supply voltage Vcc and the ground. Connected to each node of the serially connected voltage division resistors 11-0-11-N is each one end of associated selection switches 12-1-12-N. Opposite ends of these selection switches 12-1-12-N are connected together.

The selection switches 12-1-12-N are selectively switched on, one at a time, in accordance with the value of the digital signal Dn inputted to a selection switch drive circuit 30. The voltages selected by the selection switches 12-1-12-N are outputted from the DAC via a buffer amplifier 13, which is a voltage follower in the example shown herein. Thus, the digital signal Dn is converted into an analog signal Sa by the DAC 10.

The SCF 20 comprises a first capacitor 21, an operational amplifier 27, a second capacitor 22 connected between the inverting input terminal and the output terminal of the operational amplifier 27, a first switch (also referred to as input side switch) 23 provided between the input end of the SCF 20 and one end of the first capacitor 21, a second switch 24 connected between the other end of the first capacitor 21 and a node having a reference voltage Vss (e.g. ground potential), a third switch 25 connected between the reference voltage Vss and said one end of the first capacitor 21, and a fourth switch 26 connected between the other end of the first capacitor 21 and the inverting input terminal of the operational amplifier 27 to serve as an output side switch. The inverting input terminal of the operational amplifier 27 is connected to the reference voltage Vss.

A first and a second clock signals φ1 and φ2 compose 2-phase clock signals each having low (L) level periods such that when one of them is has a high (H) level the other one has the L level.

The first and second switches 23 and 24, respectively, are simultaneously switched on by the first clock signal φ1 (having H level, for example) to charge the first capacitor 21 according to the analog signal Sa, and switched off by the first clock signal φ1 (having L level, for example). Similarly, the third and fourth switches 25 and 26, respectively, are simultaneously switched on by the second clock signal φ2 (having H level, for example) to discharge the first capacitor 21, and switched off by the second clock signal φ2 (having L level, for example).

The on-off switching of the first through fourth switches 23-26 causes the SCF 20 to filter the analog signal Sa inputted thereto and outputs an output signal Sout.

In the conventional signal-processing circuit shown in FIG. 6, the output impedance of the buffer amplifier 13 of the DAC 10 is very low, which facilitates charging of the first capacitor 21 without any difficulty.

However, the buffer amplifier 13 not only incurs errors in the output of the SCF 20 due to the non-linearity of the buffer amplifier itself, but also consumes extrapower for its operation (that is proportional to the current through it).

One might consider simply omitting the buffer amplifier 13. In this instance, however, two switches (one of the switches 12-1-12-N and the input side first switch 23) are connected in series.

Usually, these switches are MOS transistors. It is usually the case that MOS transistors having high on-resistance are used in a signal processing circuit to minimize their sizes. For example, on-resistance of a MOS transistor is in the range from 1 to 2 kΩ, which is significantly larger than those of the voltage dividing resistors 11-0-11-N (which are in the range from several tens to several hundreds of Ohms).

If these highly resistive MOS transistors are connected in series, they can impede charging of the first capacitor 21. Therefore, the on-resistances of these MOS transistors must be reasonably reduced.

However, if the on-resistance of each MOS transistor is reduced by increasing its W/L ratio, the stray capacitance of the gate thereof will increase with the W/L ratio, which causes the clock feed-through of the transistor to increase. In addition, increase of the clock feed-through presents a further problem that it further increases output errors of the SCF 20.

### SUMMARY OF THE INVENTION

It is, therefore, an object of the present invention to provide an electronic circuit and a semiconductor device equipped with a voltage selection output circuit (for selecting an output voltage and outputting the selected voltage) in the form of, for example, a DAC, and equipped with an SCF, in which the number of series switches is reduced while suppressing not only output errors due to the linearity error of a buffer amplifier but also the clock feed-through of the switches.

An electronic circuit and a semiconductor device in accordance with one aspect of the invention comprises: a voltage selection output circuit for selecting a voltage from multiple different voltages by means of multiple selection switches and outputting the selected voltage; and a switched capacitor filter circuit fed with the selected voltage, the voltage selection output circuit adapted to utilize the multiple selection switches as the input side switch of the switched capacitor filter circuit by driving the multiple selection switches by a signal that incorporates therein selection conditions of the multiple selection switches and operational conditions of the input side switch of the switched capacitor filter circuit.

The voltage selection output circuit may have a resistive voltage division circuit for providing the multiple different voltages.

An electronic circuit (and a semiconductor device) in accordance with another aspect of the invention comprises: a digital-to-analog converter (DAC) for outputting an analog signal associated with a digital signal received by selecting respective multiple selection switches one selection switch at a time based on the digital signal, and a switched capacitor filter circuit fed with the analog signal, the DAC adapted to utilize the multiple selection switches as the input side switch of the switched capacitor filter circuit by driving the multiple selection switches by a signal that incorporates therein the digital signal and operational conditions of the input side switch of the switched capacitor filter circuit.

The DAC may have a resistive voltage division circuit for providing multiple different voltages that can be converted into an analog voltage via the multiple selection switches. The digital-to-analog converter circuit may include a selection switch drive circuit that has a decoder for decoding the digital signal and outputting the decoded signal, and multiple logic circuits receiving the decoded signal and a clock signal prescribing the operational conditions of the input side switch of the switched capacitor filter circuit and outputting a selection signal to the multiple selection switches.

An electronic circuit and a semiconductor device in accordance with still another aspect of the invention has a digital-to-analog converter (DAC) adapted to select respective selection switches of a first selection switch group one selection switch at a time based on a digital signal received to thereby select respective voltages, one voltage at a time, of the multiple voltages obtained by a resistive voltage division circuit, and output an analog signal associated with the digital signal as an input signal to the input side switch of a first circuit; and select respective selection switches of a second selection switch group one selection switch at a time based on the digital signal to thereby select respective voltages, one voltage at a time, of the multiple voltages, and output an analog signal associated with the digital signal as an input signal to the input side switch of a second circuit, the DAC further adapted to: utilize the first selection switch group as the input side switch of the first circuit by driving the first selection switch group by a signal that incorporates therein the digital signal and operational conditions of the input side switch of the first circuit, and utilize the second selection switch group as the input side switch of the second circuit by driving the second selection switch group by a signal that incorporates therein the digital signal and operational conditions of the input side switch of the second circuit.

The DAC may include a decoder for decoding the digital signal and outputting the decoded signal; a first logic circuit group receiving the decoded signal and a first clock signal prescribing operational conditions of the input side switch of the first circuit, and outputting a selection signal to the first selection switch group; and a second logic circuit group receiving the decoded signal and a second clock signal prescribing operational conditions of the input side switch of the second circuit, and outputting a selection signal to the second selection switch group.

An electronic circuit and a semiconductor device in accordance with a further aspect of the invention comprises: a modulator for use with a secondary DS analog-to-digital (A/D) converter, the modulator having a primary switched capacitor integrator (40) and a secondary switched capacitor integrator; and a feedback digital-to-analog converter (feedback DAC) adapted to select respective selection switches of a first selection switch group one selection switch at a time based on the digital signal received from the secondary DS A/D converter, and output an analog signal associated with the digital signal as a first feedback signal to the primary switched capacitor integrator, and select respective selection switches of a second selection switch group one selection switch at a time based on the digital signal, and output an analog signal associated with the digital signal as a second feedback signal to the secondary switched capacitor integrator, the feedback DAC further adapted to utilize the first selection switch group as the feedback input side switch of the primary switched capacitor integrator by driving the first selection switch group by a signal that incorporate therein the digital signal and operational conditions of the primary switched capacitor integrator, and utilize the second selection switch group as the feedback input side switch of the secondary switched capacitor integrator by driving the second selection switch group by a signal that incorporate therein the digital signal and operational conditions of the secondary switched capacitor integrator.

The feedback DAC may have a selection switch drive circuit that includes: a decoder for decoding the digital signal and outputs the decoded signal; a first logic circuit group receiving the decoded signal and a first clock signal prescribing operational conditions of the feedback input side switch of the primary switched capacitor integrator, and outputting a selection signal to the first selection switch group; and a second logic circuit group receiving the decoded signal and a second clock signal prescribing operational conditions of the feedback input side switch of the secondary switched capacitor integrator, and outputting a selection signal to the second selection switch group.

The inventive electronic circuit may include a voltage selection output circuit in the form of a DAC, for example, and other circuits such as an SCF in which operational conditions of the input side switch of the SCF are incorporated in the selection conditions for selecting respective multiple selection switches of the voltage selection and output circuit. Thus, dedicated input side switch of the SCF can be omitted to reduce the number of series switches such as MOS transistors.

Hence, on-resistances of the switches can be reduced accordingly. This allows use of smaller switches, which in turn facilitates reduction of clock feed-through that accompanies the operation of the switches. Thus, errors of the circuit can be reduced.

It is noted that, since no buffer amplifier is required between the switches, not only output errors due to linearity error but also the consumption current can be reduced accordingly. Moreover, dimensions of the IC (or LSI) incorporating the circuit can be reduced.

### BRIEF DESCRIPTION OF THE DRAWINGS

FIG. 1 shows the arrangement of an electronic circuit equipped with a DAC and an SCF in accordance with a first embodiment of the invention.

FIG. 2 shows an exemplary internal structure of the selection switch drive circuit shown in FIG. 1.

FIG. 3 shows the arrangement of an electronic circuit equipped with a DAC and an SCF in accordance with a second embodiment of the invention.

FIG. 4 shows a timing diagram of the clock signal shown in FIG. 3.

FIG. 5 shows the arrangement of a feedback DAC of FIG. 3.

FIG. 6 shows the arrangement of a conventional electronic circuit equipped with a DAC and a SCF.

### DETAILED DESCRIPTION OF THE PREFERRED EMBODIMENTS

An inventive electronic circuit will now be described in detail with reference to the accompanying drawings. Incidentally, since the electronic circuit of the invention is built in an LSI, it can be referred to as a semiconductor device.

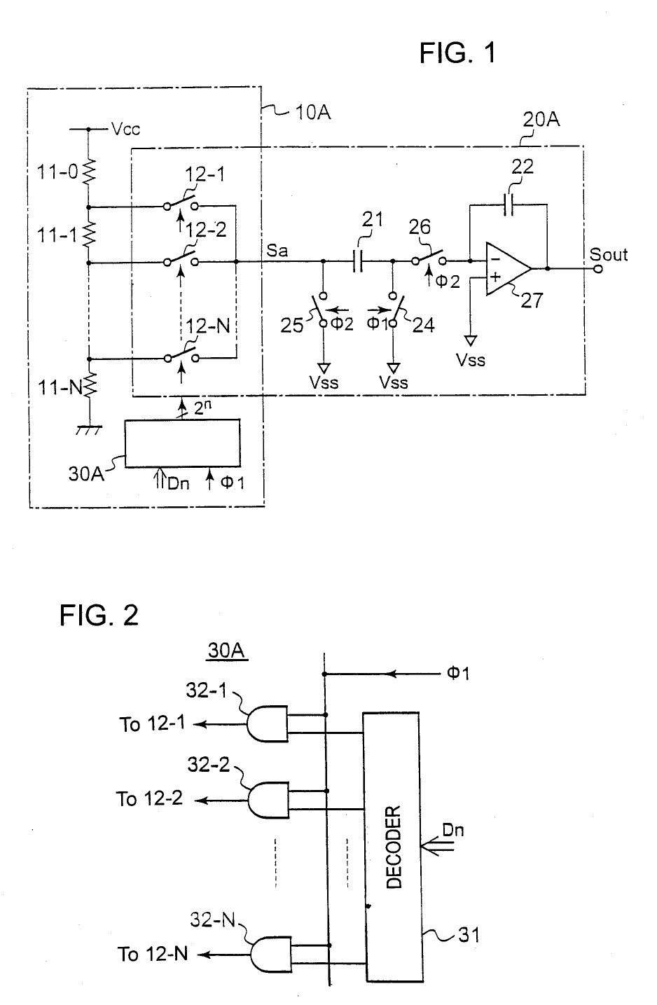

Referring to FIG. 1, there is shown the arrangement of an electronic circuit in accordance with a first embodiment of the invention.

As shown in FIG. 1, the electronic circuit is provided with a DAC 10A for converting an inputted digital signal Dn into an analog signal (analog voltage) Sa, and an SCF 20A for filtering the analog signal Sa outputted from the DAC 10A. The DAC 10A and SCF 20A may be used in various electric devices for processing signals. The DAC 10A can be any voltage selection output circuit capable of selecting voltages from multiple different voltages one at a time by means of multiple selection switches, and outputting the voltage thus selected.

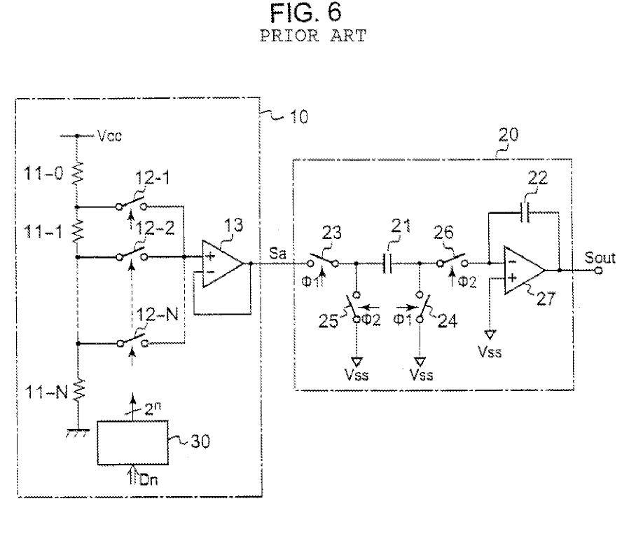

It is seen that the conventional buffer amplifier 13 as shown in FIG. 6 is omitted in FIG. 1 and that the selection switches 12-1-12-N are shared by the DAC 10A and the SCF 20A. The switches correspond to the input side switch 23 of FIG. 6. Therefore, it can be said that the selection switches 12-1-12-N functionally belong to both of the DAC 10A and the SCF 20A. It can be also said that the input side switch of the SCF 20A (that correspond to the switch 23 of FIG. 6) are omitted in that no dedicated switches is provided for the SCF 20A. This is also the case with other embodiments described below.

A selection switch drive circuit 30A receives an n-bit digital signal Dn (n=4 in the example shown herein) and a first clock signal φ1 that controls operational conditions of the input side switch of the SCF 20A, and forms selection signals (drive signals) 12-1-12-N based on the digital signal Dn and the first clock signal φ1.

An exemplary internal structure of the selection switch drive circuit 30A is shown in FIG. 2. The selection switch drive circuit 30A has a decoder 31 for decoding the digital signal Dn and outputting decoded signals, and multiple logic circuits 32-1-32-N for obtaining a selection signal to select one of the selection switches 12-1-12-N based on one of the decoded signals and the first clock signal φ1. In the example shown herein, each of the logic circuits 32-1-32-N is an AND circuit. The decoded signals are outputted from either one of the output terminals of the decoder 31.

In the selection switch drive circuit 30A, either one of the decoded signals is outputted from an associated output end of the decoder 31 according to the digital signal Dn. A selection signal is outputted from one of the AND circuits 32-1-32-N that has received the decoded signal to the selection switches 12-1-12-N at the timing of the first clock signal φ1. As a consequence, a multiplicity of divided voltages are generated by the resistive voltage division circuit 11-0-11-N, which are selected by the selection switches 12-1-12-N, one voltage at a time. The selected voltages are supplied to the SCF 20A in synchronism with the first clock signal φ1 to form an analog signal Sa.

In the SCF 20A, its first switch (i.e. the input side switch corresponding to the first switch 23 of FIG. 6) to be provided between the input side and the first capacitor 21 thereof are substituted for by the selection switches 12-1-12-N. That is, no dedicated input side switch of the SCF 20A is provided. Thus, the analog signal Sa is directly supplied from the selection switches 12-1-12-N to the first capacitor 21. Regarding other features, the arrangements of FIG. 1 and FIG. 6 are the same, so that corresponding elements are given the same reference numerals in the two figures.

In this way, by incorporating the operational conditions of the input side switch of the SCF 20A (i.e. φ1) in the digital signal Dn, the multiple selection switches 12-1-12-N are utilized as the input side switch of the SCF 20A, thereby omitting dedicated input side switch (corresponding to the switch 23 of FIG. 6) of the SCF 20A.

In the example shown in FIG. 1, either one of the selection switches 12-1-12-N is turned on in synchronism with the first clock signal φ1 according to the value of the digital signal Dn and the level of the first clock signal φ1 supplied to the selection switch drive circuit 30A. As a result, an analog signal Sa is obtained from the digital signal Dn through A/D conversion and outputted from the DAC 10A in synchronism with the first clock signal φ1.

Since the input side first switch (that correspond to the switch 23 of FIG. 6) are omitted in the SCF 20A, the analog signal Sa is inputted to the SCF 20A in synchronism with the first clock signal φ1. Thus, the second switch 24 is switched on by the first clock signal φ1 (at H level, for example) and switched off (when φ1 is at L level, for example). As the second switch 24 is switched on, the first capacitor 21 is charged by the analog signal Sa. In addition, a third and a fourth switches 25 and 26, respectively, are simultaneously turned on by the second clock φ2 (at H level, for example) to discharge the capacitor 21, and switched off (when φ2 is at L level). Through on-off switching of the second through fourth switches, the SCF 20A filters the inputted analog signal Sa, and outputs an output signal Sout.

In this way, by incorporating the first clock signal φ1 prescribing operational conditions of the input side switch of the SCF 20A in the selection conditions for selecting multiple selection switches 12-1-12-N of the DAC 10A, the multiple selection switches 12-1-12-N can be utilized as the input side switch of the SCF 20A. That is, the input side switch of the SCF 20A is omitted to reduce the number of serial MOS transistor switches in the DAC 10A and SCF 20A. As a result, on-resistance of the switches can be reduced accordingly.

In the invention, therefore, MOS transistor switches of smaller size can be used, and hence the clock feed-through involved in the switching of the MOS transistors can be reduced. Thus, errors in the circuit can be reduced accordingly.

It should be appreciated that, unlike conventional circuits, the inventive electronic circuit can be formed in an IC such as an LSI without any buffer amplifier 13. This implies that not only output errors due to linearity errors of a buffer amplifier are eliminated, but also the consumption current in the buffer amplifier can be reduced, and in addition the dimensions of area necessary for the IC (LSI) can be reduced.

Although the invention has been described with reference to an example in which the selection switch drive circuit 30A is provided in the DAC 10A as shown in FIG. 1, the invention is not limited to this example. For example, the selection switch drive circuit 30A may be provided separately from the DAC 10A or in the SCF 20A.

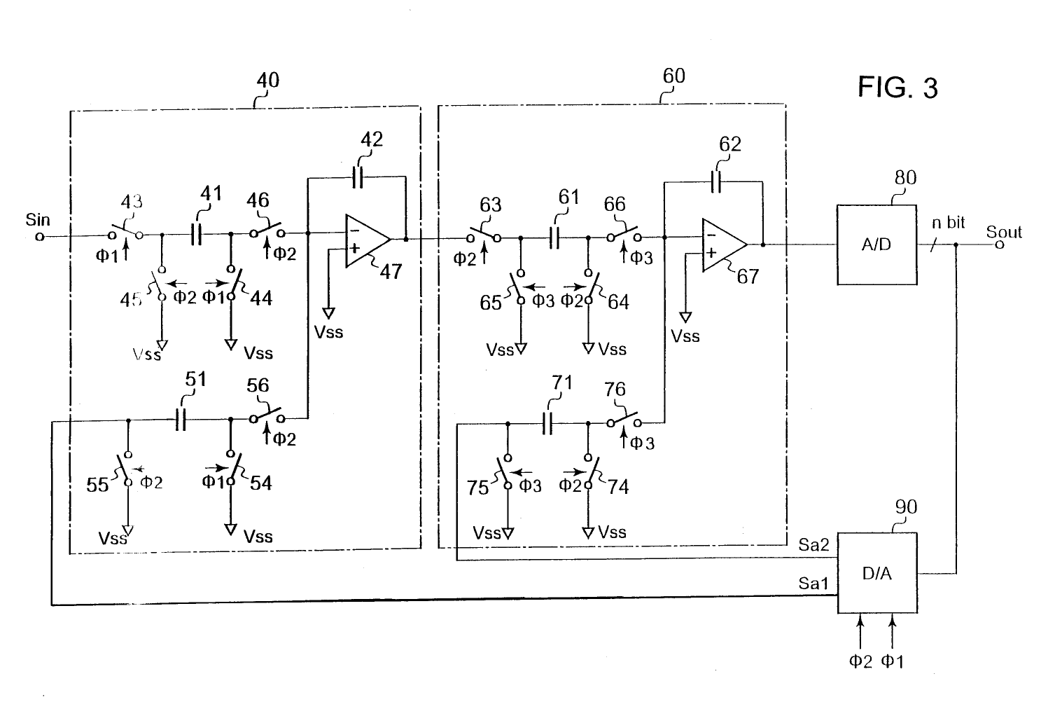

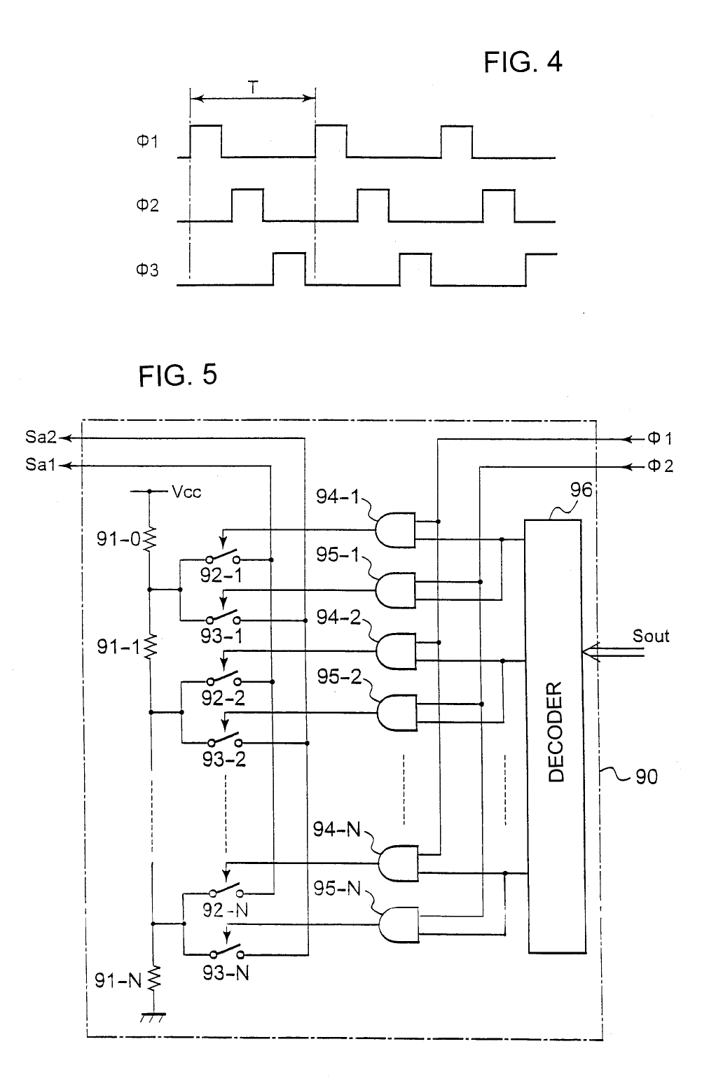

Referring to FIG. 3, there is shown an electronic circuit in accordance with a second embodiment of the invention, implemented as a modulator for use with a secondary ΔΣ A/D converter. FIG. 4 is a timing diagram of the clock signals φ1-φ3 for use in the second embodiment of FIG. 3. FIG. 5 shows an arrangement of a feedback DAC 90 for use in the second embodiment of FIG. 3.

As shown in FIG. 3, the modulator of a ΔΣ A/D converter is equipped with a primary switched capacitor integrator 40, a secondary switched capacitor integrator 60, an A/D converter 80, and a feedback DAC 90.

The first switched capacitor integrator 40 has a first capacitor 41, an operational amplifier 47, a second capacitor 42 connected between the inverting input terminal of the operational amplifier 47 and the output terminal of the integrator 40, a first switch 43 connected between the input end receiving the input signal Sin and one end of the first capacitor 41 and serving as the input side switch, a second switch 44 connected with the other end of the first capacitor 41 and a reference voltage Vss, a third switch 45 connected between the reference voltage Vss and said one end of the first capacitor 41, and a fourth switch 46 connected between the other end of the first capacitor 41 and the inverting input terminal of the operational amplifier 47 and serving as the output-side switch of the integrator 40. The inverting input terminal of the operational amplifier 47 is connected to the reference voltage Vss.

The primary switched capacitor integrator 40 also has a feedback circuit comprising a third capacitor 51 to receive a feedback signal that is supplied thereto, a sixth switch 54 connected to one end of the third capacitor 51 and the reference voltage Vss, a seventh switch 55 connected between the reference voltage Vss and the other end of the third capacitor 51, and an eighth switch 56 connected between said one end of the third capacitor 51 and the inverting input terminal of the operational amplifier 47, and serving as the output side switch of the integrator 40. In this feedback circuit, the fifth switch that is to be provided between the input side receiving the feedback signal (the side referred to as feedback input side) and one end of the third capacitor 51 is omitted.

The secondary switched capacitor integrator 60 is supplied with the output signal of the primary switched capacitor integrator 40. The secondary switched capacitor integrator 60 includes a first capacitor 61, an operational amplifier 67, a second capacitor 62 connected between the inverting input terminal and the output end of the operational amplifier 67, a first switch 63 connected between the input side of the integrator 60 receiving the output signal from the primary switched capacitor integrator 40 and one end of the first capacitor 61, and serving as the input side switch of the integrator 60, a second switch 64 connected between the other end of the first capacitor 61 and the reference voltage Vss, a third switch 65 connected between the reference voltage Vss and said one end of the first capacitor 61, and a fourth switch 66 connected between the other end of the first capacitor 61 and the inverting input terminal of the operational amplifier 67 and serving as the output side switch of the integrator 60. The inverting input terminal of the operational amplifier 67 is connected to the reference voltage Vss.

The secondary switched capacitor integrator 60 also includes a feedback circuit comprising a third capacitor 71 to receive a feedback signal that is passed thereto, a sixth switch 74 connected between one end of the third capacitor 71 and the reference voltage Vss, a seventh switch 75 connected between the reference voltage Vss and the other end of the third capacitor 71, and an eighth switch 76 connected between said one end of the third capacitor 71 and the inverting input terminal of the operational amplifier 67 and serving as an output side switch of the integrator 60. In this feedback circuit, the fifth switch that is to be provided between the input side receiving the feedback signal and one end of the third capacitor 71 is omitted.

The switches of the primary switched capacitor integrator 40 and the secondary switched capacitor integrator 60 are driven by 3-phase clock signals φ1-φ3 having a period of cycles T. Each of the 3-phase clock signals φ1-φ3 assumes H and L levels such that when either one of the three phases has H level, two other phases assume L level, as shown in FIG. 4.

The switches 43, 44, and 54 of the primary switched capacitor integrator 40 are driven by the first clock signal φ1, while the switches 45, 46, 55, and 56 are driven by the second clock signal φ2. The switches 63, 64, and 74 of the secondary switched capacitor integrator 60 are driven by the second clock signal φ2, while the switches 65, 66, 75, and 76 are driven by the third clock signal φ3. Since operation of the switched capacitor integrators 40 and 60 is essentially the same as those of the DACs and SCFs shown in FIGS. 1 and 6, further description is omitted.

The ADC 80 converts the analog signal received from the secondary switched capacitor integrator 60 into an n-bit digital signal (n=4, for example), and outputs it as output signal Sout.

The feedback DAC 90 converts the output signal Sout into an analog signal, and at the same time feeds a first feedback signal Sa1 synchronized with the first clock signal φ1 as a feedback signal back to the primary switched capacitor integrator 40. Similarly, the feedback DAC 90 feeds a second feedback signal Sa2, synchronized with the second clock signal φ2, as a feedback signal back to the secondary switched capacitor integrator 60.

Referring to FIG. 5, there is shown an exemplary arrangement of the DAC 90. A resistive voltage division circuit is connected between the power supply voltage Vcc and the ground. Connected to each node of the serially connected voltage dividing resistors 91-0-91-N is an associated selection switch of the first selection switch group 92-1-92-N and an associated selection switch of the second selection switch group 93-1-93-N. Opposite ends of the selection switches 92-1-92-N are connected together to a common node, from which node the first feedback signal Sa1 is outputted. Opposite ends of the selection switches 93-1-93-N are connected together to another common node, from which node the second feedback signal Sa2 is outputted.

A decoder 96 decodes the digital output signal Sout and outputs a decoded signal. This decoded signal is outputted from either one of the output terminals of the decoder 96 according to the value of the digital output signal Sout.

The first group of logic circuits 94-1-94-N receives the decoded signal and the first clock signal φ1 prescribing the operational conditions of the feedback-input side switch of the first switched capacitor integrator 40, and outputs a selection signal to the first selection switch group 92-1-92-N. Similarly, the second group of logic circuits 95-1-95-N receives the decoded signal and the second clock signal φ2 prescribing the operational conditions of the feedback-input side switch of the second switched capacitor integrator 60, and outputs a selection signal to the second selection switch group 93-1-93-N. Each of these logic circuits 94-1-94-N and 95-1-95-N can be an AND circuit.

In this way, the first and second clock signals, φ1 and φ2, respectively, prescribing operational conditions of the feedback-input side switch of the primary and secondary switched capacitor integrators, 40 and 60, respectively, are incorporated in the digital output signal Sout. Thus, the first and second selection switch groups 92-1-92-N and 93-1-93-N can be respectively utilized as the feedback-input side switch of the primary and secondary switched capacitor integrators 40 and 60, respectively.

In the examples shown in FIGS. 3 and 5, either one selection switch of the first selection switch group 92-1-92-N is switched on in accordance with the first clock signal φ1 and the value of the output signal Sout inputted to the DAC 90, in synchronism with the first clock signal φ1. Similarly, either one selection switch of the second selection switch group 93-1-93-N is switched on in accordance with the second clock signal φ2 and the value of the output signal Sout inputted to the DAC 90, in synchronism with the second clock signal φ2. As a result, the first and second analog signals Sa1 and Sa2 that are obtained from the output signal Sout by D/A conversion are outputted from the DAC 90 in synchronism with the first and second clock signals φ1 and φ2, respectively.

Incidentally, although the invention is described in connection with a modulator for use with a secondary AZ A/D converter, the invention can be equally applied to a modulator of higher order than 2.

The second embodiment of FIG. 3 provides the same result as the first embodiment of FIG. 1.

The invention is not limited to a modulator for use with a ΔΣ A/D converter. For example, the invention can be applied to those electronic circuits utilizing other types of switched capacitor circuits. In these cases, a first circuit having input side switch may be used in place of the primary switched capacitor integrator 40, and, in place of the secondary switched capacitor integrator 60, a second circuit having input side switch may be used.

The present invention can be suitably applied to an electronic apparatus equipped with a DAC for converting a digital signal into an analog signal and an SCF for filtering the analog signal outputted from the DAC to reduce the number of serially connected switches used and circumvent increase in clock feed-through of the switches.

1. An electronic circuit, comprising:
a voltage selection-output circuit for selecting a voltage from multiple different voltages by means of multiple selection switches and outputting the selected voltage; and
a switched capacitor filter circuit fed with the selected voltage,
said voltage selection output circuit adapted to utilize said multiple selection switches as the input side switch of said switched capacitor filter circuit by driving said multiple selection switches by a signal that incorporates therein selection conditions of said multiple selection switches and operational conditions of said input side switch of said switched capacitor filter circuit.

2. The electronic circuit in accordance with claim 1, wherein said voltage selection output circuit has a resistive voltage division circuit for providing said multiple different voltages.

3. An electronic circuit, comprising:
a digital-to-analog converter (DAC) for outputting an analog signal associated with a digital signal received by selecting respective multiple selection switches one selection switch at a time based on said digital signal, and
a switched capacitor filter circuit fed with said analog signal,
said DAC adapted to utilize said multiple selection switches as the input side switch of said switched capacitor filter circuit by driving said multiple selection switches by a signal that incorporates therein said digital signal and operational conditions of said input side switch of said switched capacitor filter circuit.

4. The electronic circuit in accordance with claim 3, wherein said DAC has a resistive voltage division circuit for providing multiple different voltages that are converted into an analog signal via said multiple selection switches.

5. The electronic circuit in accordance with claim 4, further comprising a selection switch drive circuit that has:
a decoder for decoding said digital signal and outputting the decoded signal, and
multiple logic circuits receiving said decoded signal and a clock signal prescribing operational conditions of the input side switches of said switched capacitor filter circuit, and outputting a selection signal to said multiple selection switches.

6. An electronic circuit, comprising a digital-to-analog converter (DAC), said DAC adapted to:
select respective selection switches of a first selection switch group one selection switch at a time based on a digital signal supplied thereto to thereby select respective voltages, one voltage at a time, of the multiple voltages obtained by a resistive voltage division circuit, and output an analog signal associated with said digital signal as an input signal to the input side switches of a first circuit; and
select respective selection switches of a second selection switch group one selection switch at a time based on said digital signal to thereby select respective voltages, one voltage at a time, from of said multiple voltages, and output an analog signal associated with said digital signal as an input signal to the input side switches of a second circuit,
said DAC further adapted to:
utilize said first selection switch group as the input side switch of said first circuit by driving said first selection switch group by a signal that incorporates therein said digital signal and operational conditions of said input side switch of said first circuit, and
utilize said second selection switch group as the input side switch of said second circuit by driving said second selection switch group by a signal that incorporates therein said digital signal and operational conditions of said input side switch of said second circuit.

7. The electronic circuit in accordance with claim 6, wherein said DAC has a selection switch drive circuit that include:
a decoder for decoding said digital signal and outputting the decoded signal;
a first logic circuit group receiving said decoded signal and a first clock signal prescribing operational conditions of the input side switches of said first circuit, and outputting a selection signal to said first selection switch group; and
a second logic circuit group receiving said decoded signal and a second clock signal prescribing operational conditions of the input side switches of said second circuit, and outputting a selection signal to said second selection switch group.

8. An electronic circuit, comprising:
a modulator for use with a secondary ΔΣ A/D converter, said modulator having a primary switched capacitor integrator and a secondary switched capacitor integrator; and
a feedback digital-to-analog converter (feedback DAC) adapted to
select respective selection switches of a first selection switch group one selection switch at a time based on the digital signal received from said secondary ΔΣ A/D converter, and output an analog signal associated with said digital signal as a first feedback signal to said primary switched capacitor integrator, and
select respective selection switches of a second selection switch group one selection switch at a time based on said digital signal, and output an analog signal associated with said digital signal as a second feedback signal to said secondary switched capacitor integrator,
said feedback DAC further adapted to
utilize said first selection switch group as the feedback input side switches of said primary switched capacitor integrator by driving said first selection switch group by a signal that incorporate therein said digital signal and operational conditions of said primary switched capacitor integrator, and
utilize said second selection switch group as the feedback input side switches of said secondary switched capacitor integrator by driving said second selection switch group by a signal that incorporate therein said digital signal and operational conditions of said secondary switched capacitor integrator.

9. The electronic circuit in accordance with claim 8, wherein said feedback DAC has a selection switch drive circuit that includes:
a decoder for decoding said digital signal and outputs the decoded signal;
a first logic circuit group receiving said decoded signal and a first clock signal prescribing operational conditions of said feedback input side switches of said primary switched capacitor integrator, and outputting a selection signal to said first selection switch group; and
a second logic circuit group receiving said decoded signal and a second clock signal prescribing operational conditions of said feedback input side switches of said secondary switched capacitor integrator, and outputting a selection signal to said second selection switch group.

10. A semiconductor device integrally incorporating therein:
a voltage selection-output circuit for selecting multiple different voltages one voltage at a time by means of multiple selection switch circuits, and outputting the selected voltage; and
a switched capacitor filter circuit fed with the selected voltages,
said voltage selection output circuit adapted to utilize said multiple selection switches as the input side switch of said switched capacitor filter circuit by driving said multiple selection switches by a signal that incorporates therein selection conditions of said multiple selection switches and operational conditions of said input side switch of said switched capacitor filter circuit.
